(19) United States
(12) Patent Application Publication
(10) Pub. No.: US 2026/0290439 A1
(43) Pub. Date: Sep. 24, 2026

(54) MEMORY AND READ-WRITE METHOD THEREFOR, AND ELECTRONIC DEVICE

(71) Applicant: BEIJING SUPERSTRING ACADEMY OF MEMORY TECHNOLOGY, Daxing District, Beijing (CN)

(72) Inventor: Jin DAI, Daxing District, Beijing (CN)

(73) Assignee: BEIJING SUPERSTRING ACADEMY OF MEMORY TECHNOLOGY, Daxing District, Beijing (CN)

(21) Appl. No.: 19/490,027

(22) PCT Filed: Jan. 23, 2024
(86) PCT No.: PCT/CN2024/073718

§ 371 Date: Dec. 4, 2025

(30) Foreign Application Priority Data
Aug. 10, 2023 (CN) 202311010849.2

(51) Int. Cl. G11C 11/4096; G11C 11/408; G11C 11/4094

(52) U.S. Cl. CPC G11C 11/4096; G11C 11/4085; G11C 11/4094

(57) ABSTRACT

A memory includes a three-dimensional storage array located on one side of a substrate, wherein the three-dimensional storage array includes several storage array layers; each storage array layer includes storage units, bit lines perpendicular to the substrate, and word lines parallel to the substrate; each storage array layer further includes a selection circuit, a first select line, a second select line, several third select lines and several low-level potential ends; the first select line and the second select line are parallel to the substrate; the third select lines and the word lines are arranged in one-to-one correspondence; the selection circuit is connected to the word lines, the first select line, the second select line, the several third select lines and the several low-level potential ends; and a plurality of selection circuits are used for determining selected storage array layers, and determining, word lines selected during a read-write operation.

### CROSS REFERENCE TO RELATED APPLICATIONS

The present application is the U.S. national phase of PCT Application No. PCT/CN2024/073718, filed on Jan. 23, 2024, which claims priority to Chinese Patent Application No. 202311010849.2, filed on Aug. 10, 2023, the disclosures of which are hereby incorporated herein by reference in their entireties.

### TECHNICAL FIELD

The present application relates to the technical field of semiconductors, and specifically to a memory, a reading and writing method therefor, and an electronic device.

### BACKGROUND

Memory is the main medium used for data storage. Common memory devices are mostly two-dimensional (2D) memory devices with a planar structure. With the increasing demand for integration and storage capacity of various electronic devices, three-dimensional (3D) memory devices have emerged.

The three-dimensional memory device can implement the storage and transfer of data in three-dimensional space, greatly improve the storage capacity of the memory device, reduce the storage cost, improve the integration and storage density of the memory device, which is beneficial to implementing the miniaturization of the memory device.

### SUMMARY

Embodiments of the present application provide a memory, a reading and writing method therefor, and an electronic device, and provides a method for selecting a horizontal word line during read and write operations. In order to achieve the above object, the technical solutions provided in the embodiments of the present application are as follows.

In a first aspect, a memory provided in an embodiment of the present application includes:
a base substrate;
a three-dimensional memory array located on one side of the base substrate and including a plurality of memory array layers stacked along a direction perpendicular to the base substrate, wherein a memory array layer includes memory cells arranged in a two-dimensional array, a plurality of bit lines perpendicular to the base substrate and a plurality of word lines parallel to the base substrate, and in each memory array layer, one row of memory cells is connected to one word line;
each memory array layer further includes a selection circuit, a first selection line, a second selection line, a plurality of third selection lines and a plurality of low-level potential terminals;
the first selection line and the second selection line are parallel to the base substrate, the third selection lines are perpendicular to the base substrate, and the third selection lines are disposed in a one-to-one correspondence with the word lines;
the selection circuit is connected to a plurality of the word lines, the first selection line, the second selection line, a plurality of the third selection lines and a plurality of the low-level potential terminals, respectively;
for the three-dimensional memory array, a plurality of the selection circuits are configured to determine a selected memory array layer based on a level state of a first selection line and a level state of a second selection line of a corresponding memory array layer, and to determine a selected word line during read/write operations based on a level state of a third selection line of the selected memory array layer.

Optionally, the plurality of low-level potential terminals are a plurality of power supply lines perpendicular to the base substrate;
in each of the memory array layers, the power supply line are disposed in a one-to-one correspondence with the word lines;
a plurality of the word lines disposed in a stack along the direction perpendicular to the base substrate collectively correspond to one of the power supply lines.

Optionally, a plurality of the low-level potential terminals included in all the memory array layers are a conductive wall;
all the memory array layers along the direction perpendicular to the base substrate share the conductive wall.

Optionally, a selection circuit in each of the memory array layers includes a first sub-selection circuit and a second sub-selection circuit;
for each memory array layer, a first sub-selection circuit is connected to a plurality of word lines, a first selection line and third selection lines in a same memory array layer, respectively; for the three-dimensional memory array, a first sub-selection circuit of each layer is configured to determine a memory array layer in which word lines are connected to third selection lines based on a level state of a first selection line of a corresponding memory array layer, and to determine a selected word line based on level states of the third selection lines of the memory array layer in which the word lines are connected to the third selection lines;
for each memory array layer, a second sub-selection circuit is connected to a plurality of word lines, a second selection line, and low-level potential terminals in a same memory array layer; for the three-dimensional memory array, a second sub-selection circuit of each layer is configured to determine a memory array layer in which word lines are connected to low-level potential terminals based on a level state of a second selection line of a corresponding memory array layer; wherein:
a memory array layer in which word lines are connected to third selection lines is the selected memory array layer, and a memory array layer in which word lines are connected to low-level potential terminals is an unselected memory array layer.

Optionally, the first sub-selection circuit is located on one side of the word lines, and the second sub-selection circuit is located on a same side of the word lines;
or, the first sub-selection circuit is located on a first side of the word lines, the second sub-selection circuit is located on a second side of the word lines, and the first side and the second side are disposed opposite to each other.

Optionally, the first sub-selection circuit includes a plurality of first transistors disposed in a one-to-one correspondence with the word lines;
gates of the first transistors are connected to the first selection line, first electrodes of the first transistors are connected to the word lines, and second electrodes of the first transistors are connected to the third selection lines.

Optionally, the second sub-selection circuit includes a plurality of second transistors disposed in a one-to-one correspondence with the word lines;
gates of the second transistors are connected to the second selection line, first electrodes of the second transistors are connected to the word lines, and second electrodes of the second transistors are connected to the low-level potential terminals.

Optionally, the first transistors are N-type transistors, the second transistors are N-type transistors, and the level state of the first selection line is opposite to the level state of the second selection line;
or, the first transistors are P-type transistors, the second transistors are P-type transistors, and the level state of the first selection line is opposite to the level state of the second selection line;
or, the first transistors are N-type transistors, the second transistors are P-type transistors, and the level state of the first selection line is the same as the level state of the second selection line;
or, the first transistors are P-type transistors, the second transistors are N-type transistors, and the level state of the first selection line is the same as the level state of the second selection line.

Optionally, a memory cell includes a transistor and a capacitor;
a gate of the transistor is connected to a word line, a first electrode of the transistor is connected to a bit line, a second electrode of the transistor is connected to one end of the capacitor, and the other end of the capacitor is grounded.

Optionally, the memory includes at least one of the following:
memory cells located in a same column along an extension direction of the bit lines share one bit line;
a plurality of the word lines disposed in a stack along the direction perpendicular to the base substrate collectively correspond to one of the third selection lines; and
for each memory array layer, first electrodes of transistors are connected in a one-to-one correspondence with a bit line, or first electrodes of two transistors adjacent in the direction perpendicular to the word lines are connected to a same bit line.

Optionally, the memory includes a read-write circuit, a plurality of bit line selection units and a plurality of control lines; wherein
the bit lines are connected in a one-to-one correspondence with the bit line selection units, and the control lines are connected in a one-to-one correspondence with the bit line selection units;
a bit line selection unit is configured to select a bit line based on the control of a control line to connect a selected bit line with the read-write circuit.

Optionally, the memory includes a plurality of first connection lines and/or a plurality of second connection lines;
each of the first selection lines is connected to a peripheral circuit through one of the first connection lines, the first connection lines are perpendicular to the base substrate, and a plurality of the first connection lines are arranged in a stepped pattern along the direction perpendicular to the base substrate;
each of the second selection lines is connected to a peripheral circuit through one of the second connection lines, the second connection lines are perpendicular to the base substrate, and a plurality of the second connection lines are arranged in a stepped pattern along the direction perpendicular to the base substrate.

In a second aspect, an electronic device is provided in an embodiment of the present application, and the electronic device includes any memory in the first aspect.

In a third aspect, a method for reading and writing a memory is provided in an embodiment of the present application, and the method includes:
during a write operation phase, applying a first electrical signal to a first selection line corresponding to a memory array layer to which data are to be written, and applying a second electrical signal to a second selection line corresponding to the memory array layer to which the data are to be written, so that word lines of the memory array layer to which the data are to be written are connected in a one-to-one correspondence with third selection lines to select a memory array layer to which the data are to be written;
based on the selected memory array layer to which the data are to be written, applying a third electrical signal to a third selection line corresponding to a word line connected to a row of memory cells to which the data are to be written, so that the row of memory cells connected to the word line is turned on to select the row of memory cells to which the data are to be written; and
based on the selected row of memory cells to which the data are to be written, data for a bit line connected to a memory cell in the row of memory cells are written to the memory cell.

Optionally, the reading and writing method further includes: during the write operation phase, applying a second electrical signal to a first selection line corresponding to a memory array layer to which no data are to be written, and applying a first electrical signal to a second selection line to which no data are to be written, so that word lines and low-level potential terminals of the memory array layer to which no data are to be written are connected.

The technical solutions provided in the embodiments of the present application have at least the following beneficial effects:

According to the memory in the embodiment of the present application, each memory array layer includes a selection circuit, a first selection line, a second selection line, third selection lines and low-level potential terminals, and is connected to word lines, the first selection line, the second selection line, the third selection lines and the low-level potential terminals, respectively. The plurality of selection circuits are used to determine the selected memory array layer based on the level states of the first selection lines and the second selection lines of corresponding memory array layers, and to determine the selected word line during the read/write operations based on the level state of the third selection line of the selected memory array layer. Therefore, a new designed peripheral circuit that allows for selection of an intended word line parallel to the base substrate direction during the read/write operation can be provided in the embodiment of the present application.

Additional aspects and advantages of the present application will be set forth in part in the following description, which will become apparent from the following description, or learned by the practice of the present application.

### BRIEF DESCRIPTION OF THE DRAWINGS

The abovementioned and/or additional aspects and advantages of the present application will become apparent and easy to understand from following description of embodiments in conjunction with accompanying drawings.

FIG. 1 is a schematic diagram of a structure of a k-th memory array layer included in a memory according to an embodiment of the present application.

FIG. 2 is a schematic diagram of a specific structure of the k-th memory array layer included in the memory according to an embodiment of the present application.

FIG. 3 is a schematic diagram of a structure of a transistor included in a memory according to an embodiment of the present application.

FIG. 4 is a schematic diagram of a three-dimensional structure of a memory according to an embodiment of the present application.

FIG. 5 is a flowchart of a method for reading and writing a memory according to an embodiment of the present application.

### REFERENCE NUMBERS

11-memory array layer; 12-memory cell; 13-selection circuit; 131-first sub-selection circuit; 132-second sub-selection circuit;
14-source; 15-drain; 16-semiconductor layer; 17-gate insulation layer; 18-gate

### DETAILED DESCRIPTION

The present application will be described below in detail. Examples of the embodiments of the present application are illustrated in the accompanying drawings throughout which same or similar reference signs represent the same or similar components or components with the same or similar functions. In addition, detailed descriptions about a known technology are omitted if unnecessary to the illustrated features of the present application. The embodiments described below with reference to the accompanying drawings are illustrative, and are merely intended to explain the present application, which cannot be interpreted as a limitation on the present application.

It can be understood by those skilled in the art that unless otherwise defined, all terms (including technical terms and scientific terms) used herein have the same meanings as commonly understood by those of ordinary skills in the art that to which the present application pertains. It should also be understood that terms defined in, for example, a general dictionary, should be understood as having the same meanings as those in the context of the prior art, and may not be explained as idealized or too formal meanings, unless specifically defined as herein.

It can be understood by those skilled in the art that unless otherwise specified, the singular forms “one”, “a/an”, “said”, and “the” used herein may also include plural forms. It should be further understood that wording “include” used in the specification of the present application refers to existence of feature, integer, act, operation, element, and/or component, but does not exclude existence or addition of one or more other features, integers, acts, operations, elements, components, and/or combinations thereof. It should be understood that when we stating that an element is “connected” or “coupled” to another element, such element may be directly connected or coupled to other elements, or there may be intermediate elements. Furthermore, “connected” or “coupled” used herein may include wireless connection or wireless coupling. Wording “and/or” used herein includes all or any one and all combinations of one or more listed items that are associated.

With the development of Dynamic Random Access Memory (DRAM) technologies, the planar 1T1C (i.e., one transistor and one capacitor) memory structure has reached its limit. In terms of obtaining higher capacitance, lower leakage and higher integration, the current development of 2D memory devices is limited.

For DRAM, by arranging transistors of a memory array in three dimensions instead of two dimensions, transistors in an Integrated Circuit (IC) can be placed close to each other, and a multi-layer stack can be achieved, thereby conserving planar area. At present, there are many 3D-DRAM technologies, and most 3D memory structures horizontally place 2D memory cells that is stacked in a plurality of layers, then.

At present, in term of word line designs of the 3D memory structure, some designs employs a design mode of vertical word line (that is, an extension direction of word lines is perpendicular to the base substrate), and some designs employs a design mode of horizontal word line (that is, an extension direction of word lines is parallel to the base substrate), wherein the design mode of horizontal word line has an advantage of low bit line parasitic capacitance, which can provide a more economical design.

The memory in the embodiments of the present application is a 3D memory including one transistor and a capacitor, and the word lines included in the 3D memory are horizontal word lines. A peripheral circuit of the new memory in the present application can accurately select the word lines to be selected during read/write operations, improving the performance of the memory.

Hereinafter, the technical solution of the present application and how the technical solution of the present application solves the abovementioned technical problems will be described in detail with reference to specific embodiments. The following specific embodiments may be combined with each other, and the same or similar concepts or processes may not be described in detail in some embodiments. Hereinafter, embodiments of the present application will be described with reference to the accompanying drawings.

A memory is provided in an embodiment of the present application. The memory includes a base substrate and a three-dimensional memory array located on one side of the base substrate, wherein the three-dimensional memory array includes a plurality of memory array layers stacked along a direction perpendicular to the base substrate, and the base substrate may be a semiconductor base substrate, such as a silicon base substrate.

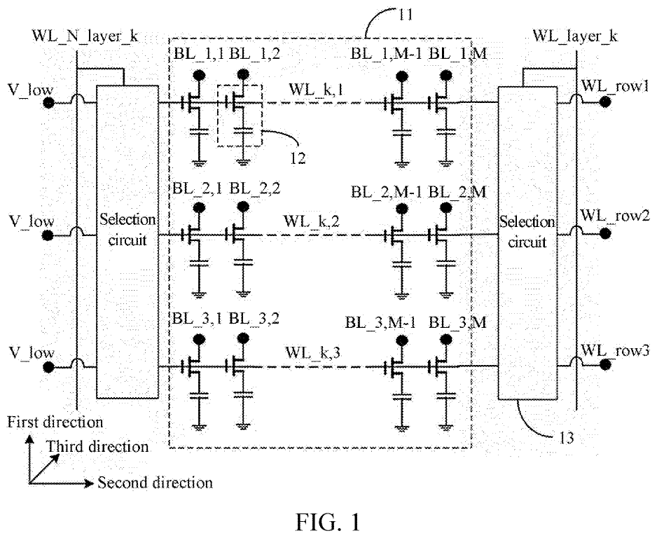

Only one memory array layer 11 (for example, a k-th memory array layer) located on one side of the base substrate is shown in FIG. 1, and the memory array layer 11 includes a plurality of memory cells 12 arranged in an array, a plurality of word lines parallel to the base substrate (such as WL-k, 1, WL-k, 2, WL-k, 3 in FIG. 1), a plurality of bit lines perpendicular to the base substrate (such as BL_1, 1, BL_1, 2, BL_1, M-1, BL_1, M and the like in FIG. 1), a selection circuit 13, a first selection line WL_layer_k, a second selection line WL_N_layer_k, a plurality of third selection line (such as Wl-row1, Wl-row2, Wl-row3 in FIG. 1) and a plurality of low-level potential terminal (at positions indicated by a plurality of V_low in FIG. 1).

As shown in FIG. 1, one row of memory cells 12 is connected to one word line. For each memory array layer, the selection circuit 13, the first selection line WL_layer_k, the second selection line WL_N_layer_k and the plurality of low-level potential terminals correspond to all the memory cells. The first selection line WL_layer_k and the second selection line WL_N_layer_k are parallel to the base substrate. The third selection lines are perpendicular to the base substrate, and the third selection lines are disposed in a one-to-one correspondence with the word lines. The selection circuit 13 is connected to the plurality of word lines, the first selection line WL_layer_k, the second selection line WL_N_layer_k, the plurality of third selection lines and the plurality of low-level potential terminals, respectively. For the three-dimensional memory array, a plurality of selection circuits 13 are configured to determine a selected memory array layer based on level states of first selection lines WL_layer_k and second selection lines WL_N_layer_k of corresponding memory array layers, and to determine a word line selected during a read/write operation based on a level state of a third selection line of the selected memory array layer.

It should be noted that the base substrate in the embodiment of the present application extends along the first direction and the second direction in FIG. 1, the plurality of word lines extend parallel to the base substrate, and the third direction in FIG. 1 refers to a direction perpendicular to a paper surface (i.e., a direction perpendicular to the base substrate).

It should be noted that the selection circuit 13 in the embodiment of the present application may be located on one side of the word lines or on opposite sides of the word lines, and FIG. 1 only illustrates a case where the selection circuit 13 is located on opposite sides of the word lines.

Specifically, as shown in FIG. 1, the plurality of word lines extend along the second direction, both the first selection line WL_layer_k and the second selection line WL_N_layer_k extend along the first direction, and the third selection line extends along the third direction. Each low-level potential terminal can be connected to a signal line. These signal lines can extend along the third direction, and each signal line is connected to a low-level potential. For example, each signal line is grounded. Of course, in practice, all signal lines can be connected together at first, and then grounded. The low-level potential in the embodiment of the present application refers to a zero potential or a negative potential.

According to the memory in the embodiment of the present application, each memory array layer includes a selection circuit, a first selection line, a second selection line, third selection lines and low-level potential terminals, and is connected to word lines, the first selection line, the second selection line, the third selection lines and the low-level potential terminals, respectively. The plurality of selection circuits are configured to determine the selected memory array layer based on the level states of the first selection lines and the second selection lines of corresponding memory array layers, and to determine the selected word line during the read/write operations based on the level state of the third selection line of the selected memory array layer. Therefore, a new designed peripheral circuit that allows for selection of an intended word line parallel to the base substrate direction during the read/write operation can be provided in the embodiment of the present application.

In a specific embodiment, a plurality of word lines disposed in a stack along the direction perpendicular to the base substrate collectively correspond to one third selection line. The third selection line (such as WL-row1, WL-row2, and WL-row3 in FIG. 1) is perpendicular to the base substrate. For a third selection line (such as Wl-row1), all memory array layers share the third selection line. The third selection line is connected to the peripheral circuit, and is configured to receive a high-level signal or a low-level signal output by the peripheral circuit. Therefore, the third selection line is disposed to save cost. Of course, in practice, it is also possible that the third selection lines included in the memory array layers are not shared. This results in more wiring, which is harmful to the integration of the device.

In an alternative embodiment, the plurality of low-level potential terminals (such as the plurality of V_low in FIG. 1) in the embodiment of the present application are a plurality of power supply lines perpendicular to the base substrate. As shown in FIG. 1, in each memory array layer, power supply lines are disposed in a one-to-one correspondence with word lines, and the plurality of word lines disposed in a stack along the direction perpendicular to the base substrate collectively correspond to one power supply line that may be grounded or connected to a negative potential signal terminal. The power supply lines are disposed to save cost.

In another alternative embodiment, the plurality of low-level potential terminals included in all memory array layers are a conductive wall shared by all the memory array layers along the direction perpendicular to the base substrate. The conductive wall can be grounded or connected to a negative potential signal terminal. In practice, this implementation can be manufactured as just one conductive wall that enables the low-level potential terminals included in all memory array layers to ground, so as to minimize the production cost.

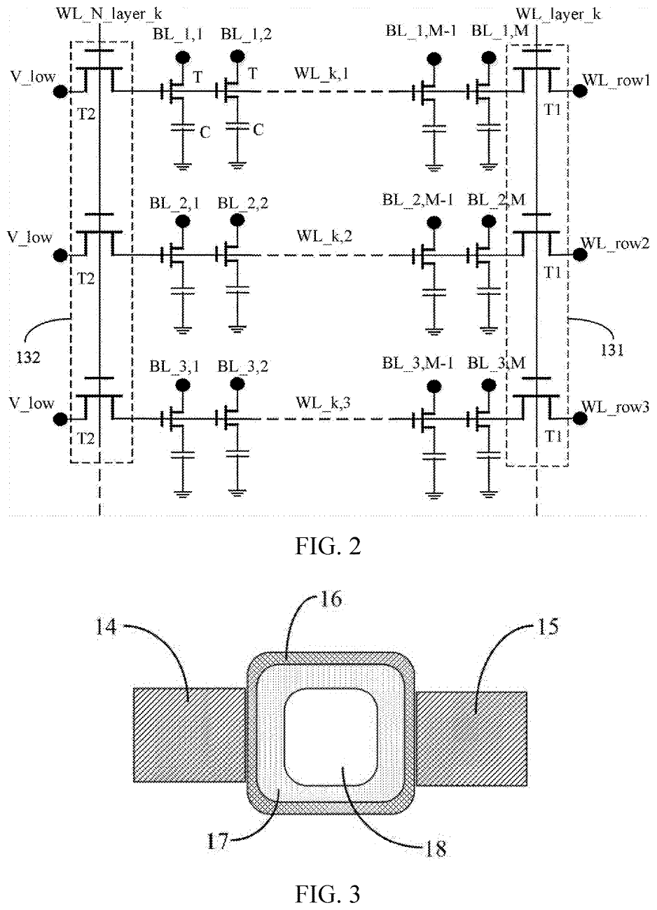

In a specific embodiment, as shown in FIG. 2, a selection circuit in each memory array layer in the embodiment of the present application includes a first sub-selection circuit 131 and a second sub-selection circuit 132. For each memory array layer, a first sub-selection circuit 131 is connected to word lines (such as WL-k, 1, WL-k, 2 and WL-k, 3 in FIG. 2), a first selection line WL_layer_k and third selection lines (such as WL-row 1, WL-row 2 and WL-row 3 in FIG. 2), respectively. For the three-dimensional memory array, a first sub-selection circuit 131 in each layer is configured to determine a memory array layer in which a word line is connected to a third selection line based on a level state of a first selection line WL_layer_k of a corresponding memory array layer, and to determine a selected word line based on a level state of a third selection line of the memory array layer in which the word line is connected to the third selection line. For each memory array layer, a second sub-selection circuit 132 is connected to a word line, a second selection line WL_N_layer_k, and a low-level potential terminal (such as a plurality of V_low in FIG. 2), respectively. For the three-dimensional memory array, a second sub-selection circuit 132 of each layer is configured to determine a memory array layer in which a word line is connected to the low-level potential terminal based on the level state of the second selection line WL_N_layer_k of the corresponding memory array layer. A memory array layer in which the word line is connected to the third selection line is determined as a selected memory array layer, and a memory array layer in which a word line is connected to the low-level potential terminal is determined as an unselected memory array layer.

In an alternative embodiment, the first sub-selection circuit 131 and the first selection line WL_layer_k are located on one side of the word lines, and the second sub-selection circuit 132 and the second selection line WL_N_layer_k are located on a same side of the word lines. In another alternative embodiment, the first sub-selection circuit 131 and the first selection line WL_layer_k are located on a first side of the word lines, the second sub-selection circuit 132 and the second selection line WL_N_layer_k are located on a second side of the word lines. The first side and the second side are disposed opposite to each other. The first sub-selection circuit 131 and the second sub-selection circuit 132 are disposed opposite to each other. The first selection line WL_layer_k and the second selection line WL_N_layer_k are disposed opposite each other. Since all of the first sub-selection circuit 131, the second sub-selection circuit 132, the first selection line WL_layer_k and the second selection line WL_N_layer_k are located at edges of the memory array layer, the design of the first sub-selection circuit 131, the second sub-selection circuit 132, the first selection line WL_layer_k and the second selection line WL_N_layer_k does not affect the overall memory design. Since the first sub-selection circuit 131 and the second sub-selection circuit 132 are opposite to each other, the peripheral circuit of the memory can have more uniform wiring.

In a specific embodiment, as shown in FIG. 2, the first sub-selection circuit 131 includes a plurality of first transistors T1 disposed in a one-to-one correspondence with the word lines. Gates of the first transistors T1 are connected to the first selection line Wl_layer_k, a first electrode of a first transistor T1 is connected to a word line (for example, a first electrode of a first one of first transistor T1 is connected to one end of the word line WL-k, 1, a first electrode of a second one of first transistor T1 is connected to one end of the word line WL-k, 2, and a first electrode of a third one of first transistor T1 is connected to one end of the word line WL-k, 3), and a second electrode of a first transistor T1 is connected to a third selection line WL-k, 3 (for example, a second electrode of the first one of first transistor T1 is connected to the third selection line WL-row1, a second electrode of the second one of first transistor T1 is connected to the third selection line WL-row2, and a second electrode of the third one of first transistor T1 is connected to the third selection line WL-row3).

In a specific embodiment, as shown in FIG. 2, the second sub-selection circuit 132 includes a plurality of second transistors T2 disposed in a one-to-one correspondence with the word lines. Gates of the second transistors T2 are connected to the second selection line WL_N_layer_k. A first electrode of a second transistor T2 is connected to a word line (for example, a first electrode of a first one of second transistor T2 is connected to the other end of the word line WL-k, 1, a first electrode of a second one of second transistor T2 is connected to the other end of the word line WL-k, 2, and a first electrode of a third one of second transistor T2 is connected to the other end of the word line WL-k, 3), and a second electrode of a second transistor T2 is connected to a low-level potential terminal (for example, V_low in FIG. 2).

In an alternative embodiment, the first transistor T1 and the second transistor T2 are of a same type. In another alternative embodiment, the first transistor T1 and the second transistor T2 are of different types, which results in high manufacturing cost and decreased yield, so that it is not a preferred design choice in practice and serves merely as a fallback solution that can be implemented.

In a specific embodiment, the first transistor T1 is an N-type transistor, and the second transistor T2 is an N-type transistor. Alternatively, the first transistor T1 is a P-type transistor, and the second transistor T2 is a P-type transistor. The level state of the first selection line WL_layer_k is opposite to the level state of the second selection line WL_N_layer_k. That is, in the embodiment of the present application, if the first transistor T1 and the second transistor T2 are of a same type, the level state of the first selection line WL_layer_k is opposite to the level state of the second selection line WL_N_layer_k.

Specifically, in the embodiment of the present application, for memory array layers in a same layer, a level state of a first selection line WL_layer_k is opposite to a level state of a second selection line WL_N_layer_k at any time. For example, if the level state of the first selection line WL_layer_k is high (that is, a logic level thereof is 1), the level state of the second selection line WL_N_layer_k is low (that is, a logic level thereof is 0). The level states of the third selection lines in the embodiment of the present application may be a high level or a low level, and the level states of the low-level potential terminals are always a low level.

In another specific embodiment, the first transistor T1 is an N-type transistor, and the second transistor T2 is a P-type transistor. Alternatively, the first transistor T1 is a P-type transistor, and the second transistor T2 is an N-type transistor. The level state of the first selection line WL_layer_k is the same as the level state of the second selection line WL_N_layer_k. That is, in the embodiment of the present application, if the first transistor T1 and the second transistor T2 are of different types, the level state of the first selection line WL_layer_k is the same as the level state of the second selection line WL_N_layer_k.

Specifically, in the embodiment of the present application, for memory array layers in a same layer, a level state of a first selection line WL_layer_k is the same as a level state of a second selection line WL_N_layer_k at any time. For example, if the level state of the first selection line WL_layer_k is high (that is, a logic level is 1), the level state of the second selection line WL_N_layer_k is also high. When the level state of the first selection line WL_layer_k is low (i.e., the logic level is 0), the level state of the second selection line WL_N_layer_k is also low.

As shown in FIG. 2, the embodiment of the present application will be described by taking both the first transistor T1 and the second transistor T2 being of a same N-type transistor as an example.

The first selection line WL_layer_k and the second selection line WL_N_layer_k in the embodiment of the present application serve as memory array layer selection lines. That is, the selected memory array layer is determined by the level state of the first selection line WL_layer_k and the level state of the second selection line WL_N_layer_k. Specifically, if a k-th memory array layer needs to be selected, a level state of a first selection line WL_layer_k included in the k-th memory array layer is high (that is, the peripheral circuit outputs a high-level signal to a first selection line WL_layer_k), and a level state of a second selection line WL_N_layer_k included in the k-th memory array layer is low (that is, the peripheral circuit outputs a low-level signal to a second selection line WL_N_layer_k). For all memory array layers that are not selected, a level state of a first selection line WL_layer_k included in each memory array layer is low, and a level state of a second selection line WL_N_layer_k included in each memory array layer is high.

As shown in FIG. 2, a memory cell in the embodiment of the present application includes a transistor T and a capacitor disposed in a horizontal two-dimensional arrangement. A gate of the transistor T is connected to a word line, a first electrode of the transistor T is connected to a bit line, a second electrode of the transistor T is connected to one end of the capacitor C, and the other end of the capacitor C is grounded. Although the transistor T in the embodiment of the present application is an N-type transistor, the transistor T may be a P-type transistor in practice.

It should be noted that the first electrode of the transistor (e.g. transistor T, first transistor T1, and second transistor T2) in the embodiment of the present application refers to a source of the transistor, and the second electrode of the transistor refers to the drain of the transistor. Alternatively, the first electrode of the transistor refers to the drain of the transistor, the second electrode of the transistor refers to the source of the transistor, and the first electrode and the second electrode of the transistor may be interchanged, which is not limited herein.

In a specific embodiment, all channels of the transistor T, the first transistor T1 and the second transistor T2 in the embodiment of the present application are horizontal channels. As shown in FIG. 3, the transistor T includes a source 14, a drain 15, a semiconductor layer 16, a gate insulation layer 17 and a gate electrode 18, wherein the semiconductor layer 16 is disposed around the gate electrode 18. Each of first transistor T1 and the second transistor T2 can also be disposed as shown in FIG. 3. Specifically, the semiconductor layer is preferably a metal oxide semiconductor such as Indium Gallium Zinc Oxide (IGZO). When the metal oxide material belong to IGZO, low leakage current of the transistor (the leakage current is less than or equal to 10⁻¹⁵A) ensures a low refresh rate of a dynamic memory.

It should be noted that the material of the metal oxide may be ITO, IWO, ZnOx, InOx, In2O3, InWO, SnO2, TiOx, InSnOx, ZnxOyNz, MgxZnyOz, InxZnyOz, InxGayZnzOa, ZrxInyZnzOa, HfxInyZnzOa, SnxInyZnzOa, AlxSnyInzZnaOd, SixInyZnzOa, ZnxSnyOz, AlxZnySnzOa, GaxZnySnzOa, ZrxZnySnzOa, InGaSiO, IAZO and the like, as long as the leakage current of the transistor can meet the requirements, which can be adjusted according to the actual situation.

As shown in FIG. 2, in the embodiment of the present application, a plurality of word lines disposed in a stack along the direction perpendicular to the base substrate collectively correspond to a third selection line that serves as a word line selection line. That is, the selected word line in the selected memory array layer is determined by the level state of the third selection line. Specifically, if the k-th memory array layer is selected, a plurality of third selection lines and a plurality of word lines of the k-th memory array layer are connected in a one-to-one correspondence. When the level state of the third selection line is a high level, a word line connected to a high-level third selection line is selected, and when the level state of the third selection line is a low level, a word line connected to a low-level third selection line is not selected. For example, the third selection line WL-row1 connected to a word line WL-k, 1 is set to the high-level to select the word line WL-k, 1 (that is, the peripheral circuit outputs a high-level signal to the third selection line Wl-row1), and third selection lines connected to the other word lines are set to the low-level (that is, the peripheral circuit outputs low-level signals to the third selection lines connected to the other word lines), thereby turning on a transistor T connected to the word line WL-k, 1, and then writing data of the bit lines BL_1, 1, BL_1, 2, BL_1, M-1, and BL_1, M to the capacitor C, or reading data stored in the capacitor C through the bit lines BL_1, 1, BL_1, 2, BL_1, M-1, and BL_1, M. Similarly, when another word line is selected, data writing and data reading of memory cells in corresponding rows can be implemented.

Specifically, as shown in FIG. 2, memory cells located in a same column along an extension direction of a bit line share one bit line. That is, for one bit line (for example, bit line BL_1, 1), all memory array layers stacked along the extension direction of the bit line share the bit line. For each memory array layer, first electrodes of transistors T included in the memory cells are connected in a one-to-one correspondence with bit lines, which is simple and easy to manufacture.

In an alternative embodiment, for each memory array layer, first electrodes of two transistors T adjacent along a direction perpendicular to the word lines (for example, two adjacent transistors located in a first column in FIG. 2) are connected to a same bit line, which can save the quantity of bit lines, reduce the dimension of the memory, thereby improving the integration of the device.

As shown in FIG. 2, the memory in the embodiment of the present application includes a read-write circuit, a plurality of bit line selection units and a plurality of control lines, wherein bit lines are connected in a one-to-one correspondence with the bit line selection units, and the control lines are connected in a one-to-one correspondence with the bit line selection units. A bit line selection unit is configured to select a bit line based on control of a control line to connect the selected bit line with the read-write circuit. Specifically, the bit line selection units are located at the bottom or top of the three-dimensional memory array. The bit line selection unit forms an array, wherein a row of bit line selection units corresponding to a word line is turned on through the control of the control line, and is connected to a row of read-write circuits. Specifically, when writing data, the read-write circuit transmits data to the row of memory units through bit lines. When reading data, the read-write circuit can receive data transmitted by the row of memory units through the bit lines to accomplish reading of the row of memory units.

In a specific embodiment, the memory further includes a plurality of first connection lines and/or a plurality of second connection lines, wherein each first selection line is connected with the peripheral circuit through a first connection line. The first connection lines are perpendicular to the base substrate. The plurality of first connection lines are arranged in a stepped pattern along the direction perpendicular to the base substrate. Each second selection line is connected with the peripheral circuit through a second connection line, and the second connection line is perpendicular to the base substrate. The plurality of second connection lines are arranged in a stepped pattern along the direction perpendicular to the base substrate. According to this arrangement mode, the first selection lines included in different memory array layers can be connected to the peripheral circuit in the smallest wiring space to receive electrical signals output by the peripheral circuit, and second selection lines included in different memory array layers can be connected to the peripheral circuit to receive electrical signals output by the peripheral circuit to accomplish the control of the selection circuit.

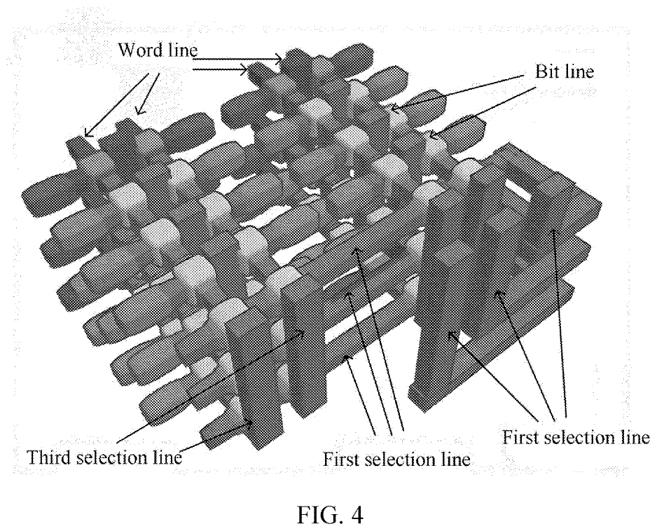

Specifically, as shown in FIG. 4, only the disposing form of the first selection lines and the first connection lines is shown in the drawing, and the disposing form of the second selection lines and the second connection lines is similar, which is not repeated herein. FIG. 4 illustrates three first selection lines located in three adjacent memory array layers, wherein each of first selection lines is connected with the peripheral circuit through correspondingly connected first connection lines, top ends of the plurality of first connection lines are flush with each other, and bottom ends of the plurality of first connection lines are respectively located in different memory array layers. Different memory array layers are disposed in a stack, the bottom ends of the plurality of first connection lines are located in different planes, the first connection lines are arranged in a stepped pattern, and can be implemented by vias in a stepped pattern during manufacturing.

Based on the same inventive concept, an electronic device is provided in an embodiment of the present application. The electronic device includes a memory according to any of the above embodiments.

The electronic device includes the abovementioned memory. Therefore, the electronic device has same beneficial effects as the abovementioned memory, which is not repeated herein.

Specifically, the electronic device refers to a storage equipment, a smartphone, a computer, a tablet, an artificial intelligence device, a wearable device or a power bank.

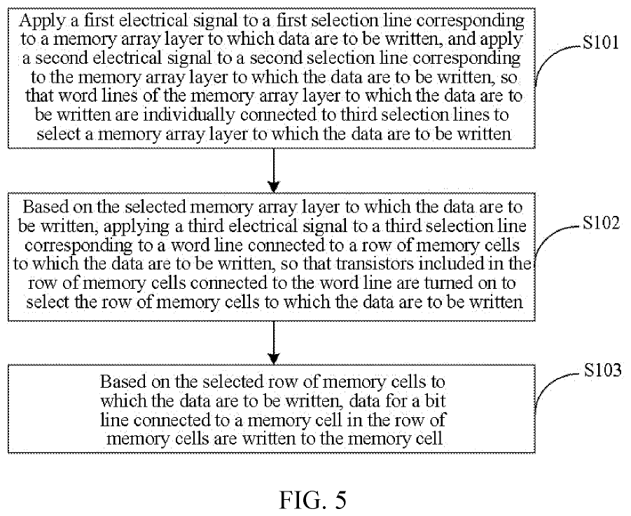

Based on the same inventive concept, a method for reading and writing a memory is provided in an embodiment of the present application. As shown in FIG. 5, a memory write operation phase includes acts S101 to S103.

In the act S101, during a write operation phase, a first electrical signal is applied to a first selection line corresponding to a memory array layer to which data are to be written, and a second electrical signal is applied to a second selection line corresponding to the memory array layer to which the data are to be written, so that word lines of the memory array layer to which the data are to be written are connected in a one-to-one correspondence with third selection lines to select a memory array layer to which the data are to be written.

In the act S102, based on the selected memory array layer to which the data are to be written, a third electrical signal is applied to a third selection line corresponding to a word line connected to a row of memory cells to which the data are to be written, so that transistors included in the row of memory cells connected to the word line are turned on to select the row of memory cells to which the data are to be written.

In the act S103, based on the selected row of memory cells to which the data are to be written, data for a bit line connected to a memory cell in the row of memory cells are written to the memory cell.

Specifically, the memory array layer included in the memory is configured as the following description in which FIG. 2 is taken as an example. During the write operation phase, a high-level signal is applied to a first selection line WL_layer_k corresponding to a memory array layer to which data are to be written, and a low-level signal is applied to a second selection line WL_N_layer_k, so that a first transistor T1 is turned on, a second transistor T2 is turned off, and word lines are connected in a one-to-one correspondence with third selection lines. Thereafter, a high-level signal is applied to a third selection line connected to a word line to which data are to be written. For example, when the word line to be written is WL-K, 1, the word line WL-K, 1 receives the high-level signal and controls a first row of transistors T to be turned on, so that data of a bit line connected to the first row of transistors T can be written. In addition, a low-level signal is applied to the other third selection lines (that is, third selection lines connected to word lines that are not necessary to be written), so that the other transistors included in the memory cell are turned off, so that the memory cell cannot be written even if there are data in a bit line.

In an alternative embodiment, if the memory cell in the embodiment of the present application includes a transistor and a capacitor, during the read operation phase of the memory, a high-level signal is applied to a first selection line WL_layer_k corresponding to a memory array layer in which data are to be read, and a low-level signal is applied to a second selection line WL_N_layer_k, so that a first transistor T1 is turned on, a second transistor T2 is turned off, and each word line is connected in a one-to-one correspondence with a third selection line. Thereafter, a high-level signal is applied to a third selection line connected to a word line in which data are to be read. For example, a word line WL-K, 1, in which the data are to be read, receives the high-level signal and controls a first row of transistors T to be turned on, so that data stored in a first row of memory cells can be transmitted to corresponding bit lines, and the stored data can be read by a read-write circuit connected to the bit lines. In addition, a low-level signal is applied to the other third selection lines (i.e., the third selection lines connected to a word line that is not necessary to be read), so that all the other transistors included in the memory cell are in an off state. In addition, during the read operation phase, the method further includes: for a memory array layer that does not need to read data, a low-level signal is applied to its corresponding first selection line WL_layer_k, and a high-level signal is applied to a second selection line WL_N_layer_k that does not need to read data.

In a specific embodiment, the write operation phase further includes: applying a second electrical signal to a first selection line corresponding to a memory array layer to which no data are to be written, and applying a first electrical signal to a second selection line to which no data are to be written, so that word lines and low-level potential terminals of the memory array layer to which no data are to be written are connected.

Specifically, the memory array layer included in the memory is configured as the following description in which FIG. 2 is taken as an example. For a memory array layer to which no data are to be written during the write operation phase, a low-level signal is applied to its first selection line WL_layer_k, and a high-level signal is applied to its second selection line WL_N_layer_k to which no data are to be written.

In summary, by applying the embodiments of the present application, at least the following beneficial effects can be achieved.

According to the memory in the embodiment of the present application, each memory array layer includes a selection circuit, a first selection line, a second selection line, third selection lines and low-level potential terminals, and is connected to word lines, the first selection line, the second selection line, the third selection lines and the low-level potential terminals, respectively. The plurality of selection circuits are used to determine the selected memory array layer based on the level states of the first selection lines and the second selection lines of corresponding memory array layers, and to determine the selected word line during the read/write operations based on the level state of the third selection line of the selected memory array layer. Therefore, a new designed peripheral circuit that allows for selection of an intended word line parallel to the base substrate direction during the read/write operation can be provided in the embodiment of the present application.

Those skilled in the art can understand that acts, measures and solutions in various operations, methods, and the process already discussed in the present application may be alternated, changed, combined or deleted. Further, other acts, measures and solutions in various operations, methods and processes already discussed in the present application may also be alternated, changed, rearranged, divided, combined or deleted. Further, acts, measures and schemes in the prior arts having the same functions with those in various operations, methods and processes disclosed in the present application may also be alternated, changed, rearranged, divided, combined or deleted.

In the description of the present application, the directions or positional relationships indicated by the terms “center”, “upper”, “lower”, “front”, “back”, “left”, “right”, “vertical”, “horizontal”, “top”, “bottom”, “inner”, “outer” and the like are based on the exemplary directions or positional relationships shown in the drawings, and are intended to facilitate or simplify the description of the embodiments of the present application, and do not to indicate or imply that a referred apparatus or component must be in a specific orientation, be constructed and operate in a specific orientation, and therefore cannot be construed as limiting the present application.

Terms “first” and “second” are only used for description and should not be construed as indicating or implying relative importance or implicitly indicating the number of indicated technical features. Therefore, features defined by “first” and “second” may explicitly or implicitly include one or more such features. In the description of the present invention, “plurality of” means two or more than two, unless otherwise specified.

The above is only part of the implementations of the present application, and it should be noted that for those of ordinary skills in the art, without departing from the principles of the present application, various improvements and modifications may be made, and these improvements and modifications should also be regarded as being covered by the protection scope of the present application.

1. A memory comprising:
a base substrate;
a three-dimensional memory array located on one side of the base substrate and comprising a plurality of memory array layers stacked along a direction perpendicular to the base substrate, wherein a memory array layer comprises memory cells arranged in a two-dimensional array, a plurality of bit lines perpendicular to the base substrate and a plurality of word lines parallel to the base substrate, and in each memory array layer, one row of memory cells is connected to one word line;
each memory array layer further comprises a selection circuit, a first selection line, a second selection line, a plurality of third selection lines and a plurality of low-level potential terminals;
the first selection line and the second selection line are parallel to the base substrate, the third selection lines are perpendicular to the base substrate, and the third selection lines are disposed in a one-to-one correspondence with the word lines;
the selection circuit is connected to a plurality of the word lines, the first selection line, the second selection line, a plurality of the third selection lines and a plurality of the low-level potential terminals, respectively;
for the three-dimensional memory array, a plurality of the selection circuits are configured to determine a selected memory array layer based on a level state of a first selection line and a level state of a second selection line of a corresponding memory array layer, and to determine a selected word line during read/write operations based on a level state of a third selection line of the selected memory array layer.

2. The memory of claim 1, wherein the plurality of low-level potential terminals are a plurality of power supply lines perpendicular to the base substrate;
in each of the memory array layers, the power supply line are disposed in a one-to-one correspondence with the word lines;
a plurality of the word lines disposed in a stack along the direction perpendicular to the base substrate collectively correspond to one of the power supply lines.

3. The memory of claim 1, wherein a plurality of the low-level potential terminals included in all the memory array layers are a conductive wall;
all the memory array layers along the direction perpendicular to the base substrate share the conductive wall.

4. The memory of claim 1, wherein the selection circuit in each of the memory array layers comprises a first sub-selection circuit and a second sub-selection circuit;
for each memory array layer, the first sub-selection circuit is connected to the plurality of word lines, the first selection line and the third selection line in a same memory array layer, respectively; for the three-dimensional memory array, the first sub-selection circuit of each layer is configured to determine a memory array layer in which the word lines are connected to the third selection lines based on a level state of a first selection line of a corresponding memory array layer, and to determine a selected word line based on level states of the third selection lines of the memory array layer in which the word lines are connected to the third selection lines;
for each memory array layer, the second sub-selection circuit is connected to the plurality of word lines, the second selection line, and low-level potential terminals in a same memory array layer, respectively; for the three-dimensional memory array, the second sub-selection circuit of each layer is configured to determine a memory array layer in which the word lines are connected to the low-level potential terminals based on a level state of a second selection line of a corresponding memory array layer; wherein:
the memory array layer in which the word lines are connected to the third selection lines is the selected memory array layer, and the memory array layer in which the word lines are connected to the low-level potential terminals is an unselected memory array layer.

5. The memory of claim 4, wherein the first sub-selection circuit is located on one side of the word lines, and the second sub-selection circuit is located on a same side of the word lines;
or, the first sub-selection circuit is located on a first side of the word lines, the second sub-selection circuit is located on a second side of the word lines, and the first side and the second side are disposed opposite to each other.

6. The memory of claim 4, wherein the first sub-selection circuit comprises a plurality of first transistors disposed in a one-to-one correspondence with the word lines;
gates of the first transistors are connected to the first selection line, first electrodes of the first transistors are connected to the word lines, and second electrodes of the first transistors are connected to the third selection lines.

7. The memory of claim 6, wherein the second sub-selection circuit comprises a plurality of second transistors in a one-to-one correspondence with the word lines;
gates of the second transistors are connected to the second selection line, first electrodes of the second transistors are connected to the word lines, and second electrodes of the second transistors are connected to the low-level potential terminals.

8. The memory of claim 7, wherein the first transistors are N-type transistors, the second transistors are N-type transistors, and the level state of the first selection line is opposite to the level state of the second selection line;
or, the first transistors are P-type transistors, the second transistors are P-type transistors, and the level state of the first selection line is opposite to the level state of the second selection line;
or, the first transistors are N-type transistors, the second transistors are P-type transistors, and the level state of the first selection line is the same as the level state of the second selection line;
or, the first transistors are P-type transistors, the second transistors are N-type transistors, and the level state of the first selection line is the same as the level state of the second selection line.

9. The memory of claim 1, wherein a memory cell comprises one transistor and one capacitor;
a gate of the transistor is connected to a word line, a first electrode of the transistor is connected to a bit line, a second electrode of the transistor is connected to one end of the capacitor, and the other end of the capacitor is grounded.

10. The memory of claim 9, comprising at least one of following:
memory cells located in a same column along an extension direction of the bit lines sharing one bit line;
a plurality of the word lines disposed in a stack along the direction perpendicular to the base substrate collectively corresponding to one of the third selection lines; and
for each memory array layer, first electrodes of transistors connected in a one-to-one correspondence with the bit lines, or first electrodes of two transistors adjacent in a direction perpendicular to the word lines connected to a same bit line.

11. The memory of claim 9, comprising a read-write circuit, a plurality of bit line selection units, and a plurality of control lines;
wherein the bit lines are connected in a one-to-one correspondence with the bit line selection units, and the control lines are connected in a one-to-one correspondence with the bit line selection units;
a bit line selection unit is configured to select a bit line based on control of a control line to connect a selected bit line with the read-write circuit.

12. The memory of claim 1, comprising a plurality of first connection lines and/or a plurality of second connection lines; wherein
each of the first selection lines is connected to a peripheral circuit through one of the first connection lines, the first connection lines are perpendicular to the base substrate, and a plurality of the first connection lines are arranged in a stepped pattern along the direction perpendicular to the base substrate;
each of the second selection lines is connected to the peripheral circuit through one of the second connection lines, the second connection lines are perpendicular to the base substrate, and a plurality of the second connection lines are arranged in a stepped pattern along the direction perpendicular to the base substrate.

13. An electronic device comprising the memory of claim 1.

14. A method for reading and writing the memory of claim 1, comprising:
during a write operation phase, applying a first electrical signal to a first selection line corresponding to a memory array layer to which data are to be written, and applying a second electrical signal to a second selection line corresponding to the memory array layer to which the data are to be written, so that word lines of the memory array layer to which the data are to be written are connected in a one-to-one correspondence with the third selection lines to select the memory array layer to which the data are to be written;
based on the selected memory array layer to which the data are to be written, applying a third electrical signal to a third selection line corresponding to a word line connected to a row of memory cells to which the data are to be written, so that the row of memory cells connected to the word line is turned on to select the row of memory cells to which the data are to be written;
based on the selected row of memory cells to which the data are to be written, data for a bit line connected to a memory cell in the row of memory cells are written to the memory cell.

15. The reading and writing method of claim 14, further comprising: during the write operation phase, applying the second electrical signal to a first selection line corresponding to a memory array layer to which no data are to be written, and applying the first electrical signal to a second selection line to which no data are to be written, so that word lines and low-level potential terminals of the memory array layer to which no data are to be written are connected.

16. The memory of claim 2, comprising a plurality of first connection lines and/or a plurality of second connection lines; wherein
each of the first selection lines is connected to a peripheral circuit through one of the first connection lines, the first connection lines are perpendicular to the base substrate, and a plurality of the first connection lines are arranged in a stepped pattern along the direction perpendicular to the base substrate;
each of the second selection lines is connected to the peripheral circuit through one of the second connection lines, the second connection lines are perpendicular to the base substrate, and a plurality of the second connection lines are arranged in a stepped pattern along the direction perpendicular to the base substrate.

17. The memory of claim 3, comprising a plurality of first connection lines and/or a plurality of second connection lines; wherein
each of the first selection lines is connected to a peripheral circuit through one of the first connection lines, the first connection lines are perpendicular to the base substrate, and a plurality of the first connection lines are arranged in a stepped pattern along the direction perpendicular to the base substrate;
each of the second selection lines is connected to the peripheral circuit through one of the second connection lines, the second connection lines are perpendicular to the base substrate, and a plurality of the second connection lines are arranged in a stepped pattern along the direction perpendicular to the base substrate.

18. The memory of claim 4, comprising a plurality of first connection lines and/or a plurality of second connection lines; wherein
each of the first selection lines is connected to a peripheral circuit through one of the first connection lines, the first connection lines are perpendicular to the base substrate, and a plurality of the first connection lines are arranged in a stepped pattern along the direction perpendicular to the base substrate;
each of the second selection lines is connected to the peripheral circuit through one of the second connection lines, the second connection lines are perpendicular to the base substrate, and a plurality of the second connection lines are arranged in a stepped pattern along the direction perpendicular to the base substrate.

19. An electronic device comprising the memory of claim 9.

20. An electronic device comprising the memory of claim 10.
